(19) United States
(12) Patent Application Publication
(10) Pub. No.: US 2025/0169242 A1
(43) Pub. Date: May 22, 2025

(54) INFRARED LIGHT-EMITTING DIODE, INFRARED LIGHT-EMITTING DIODE PACKAGE, AND LIGHT-EMITTING DEVICE

(71) Applicant: Tianjin Sanan Optoelectronics Co., Ltd., Tianjin (CN)

(72) Inventors: Jingqi BAI, Tianjin (CN); Yanbin FENG, Tianjin (CN); Jin WANG, Tianjin (CN); Huanshao KUO, Tianjin (CN); Kunhuang CAI, Tianjin (CN); Chaoyu WU, Tianjin (CN); Duxiang WANG, Tianjin (CN); Yuren PENG, Tianjin (CN)

(73) Assignee: Tianjin Sanan Optoelectronics Co., Ltd., Tianjin (CN)

(21) Appl. No.: 18/943,893

(22) Filed: Nov. 12, 2024

(30) Foreign Application Priority Data
Nov. 17, 2023 (CN) 202311544161.2

(51) Int. Cl. H01L 33/40; H01L 33/30

(52) U.S. Cl. CPC H10H 20/832; H10H 20/824

(57) ABSTRACT

Disclosed are an infrared light-emitting diode, an infrared light-emitting diode package, and a light-emitting device. The infrared light-emitting diode includes a semiconductor epitaxial lamination layer, a first electrode, and an adhesion layer. The semiconductor epitaxial lamination layer includes a first type semiconductor layer, an active layer, and a second type semiconductor layer. The first type semiconductor layer includes a first ohmic contact layer, a first window layer, and a first cladding layer. The first electrode located on the first type semiconductor includes a main electrode and multiple extending electrodes. The extending electrodes extend outward from the main electrode. The adhesion layer is located between the first window layer and the main electrode. The present invention enhances the adhesion between the first electrode and the semiconductor epitaxial lamination layer via the adhesion layer, improves the bonding force of the electrode, thereby elevating the reliability of the infrared light-emitting diode.

### CROSS-REFERENCE TO RELATED APPLICATION

This application claims the priority benefit of China application serial no. 202311544161.2, filed on Nov. 17, 2023. The entirety of the above-mentioned patent application is hereby incorporated by reference herein and made a part of this specification.

### BACKGROUND

### Technical Field

The disclosure relates to a technical field of semiconductor manufacturing, and in particular to an infrared light-emitting diode and a light-emitting device.

### Description of Related Art

Light-emitting diodes (LEDs) have advantages of high luminous intensity, high efficiency, small size, and long lifespan, and are considered one of the most promising light sources currently. Infrared light-emitting diodes, due to their specific waveband, as well as low power consumption and high reliability, are widely applied in fields such as security monitoring, wearable devices, space communication, remote control, medical equipment, light sources for sensors, and night illumination.

To elevate the light-emitting efficiency, several methods may be employed, including improving the quality of epitaxial growth, increasing the probability of the combination of electrons and holes, and elevating the internal quantum efficiency (IQE). In another aspect, if the light generated by the LED cannot be effectively extracted, some light may be confined within the LED due to total reflection factors, repeatedly reflecting or refracting internally, and ultimately being absorbed by the electrode or the light-emitting layer, which prevents brightness from being elevated. Therefore, methods such as surface roughening or altering the geometric structure may be used to elevate the external quantum efficiency (EQE), thereby elevating the luminous brightness and light-emitting efficiency of the LED.

The window layer material of the conventional infrared LED generally is AlₓGa₁₋ₓInAs, and AlₓGa₁₋ₓInAs may be roughened by wet process etching to obtain a rough light-emitting surface, thereby elevating the light extraction efficiency of the infrared light-emitting diode. However, poor adhesion between the electrode and the window layer material may lead to issues such as electrode detachment and poor current expansion in the infrared LED, resulting in problems of electrode detachment and low brightness.

### SUMMARY

To solve the aforementioned problems, the disclosure proposes an infrared light-emitting diode. The infrared light-emitting diode includes a semiconductor epitaxial lamination layer, a first electrode, and an adhesion layer. The semiconductor epitaxial lamination layer has a first surface and a second surface opposite to each other, and includes a first type semiconductor layer, an active layer, and a second type semiconductor layer stacked in sequence along a direction from the first surface towards the second surface. The first type semiconductor layer includes a first ohmic contact layer, a first window layer, and a first cladding layer along the direction. The first electrode is located on the first type semiconductor layer, and includes a main electrode and multiple extending electrodes. The extending electrodes extend outward from the main electrode. The adhesion layer is located between the first window layer and the main electrode of the first electrode.

In some selectable embodiments, the adhesion layer may not contain Al element.

In some selectable embodiments, a material of the adhesion layer is InGaAs, GaAs, InP, or GaInP.

In some selectable embodiments, a thickness of the adhesion layer is 0.3 μm to 0.7 μm.

In some selectable embodiments, a doping concentration of the adhesion layer is 1×10¹⁷/cm³ to 9×10¹⁷/cm³.

In some selectable embodiments, at a horizontal projection position of the extending electrodes, the adhesion layer is located between the first ohmic contact layer and the first window layer.

In some selectable embodiments, a material of the first window layer is AlₓGa₁₋ₓInAs, where 0<X≤0.25.

In some selectable embodiments, the first window layer includes a first part covered by the first electrode, and a thickness of the first part is 6 μm to 8 μm.

In some selectable embodiments, the first window layer includes a second part not covered by the first electrode, and a thickness of the second part is 0.5 μm to 1.5 μm.

In some selectable embodiments, a surface of the second part is exposed and patterned or roughened to provide a light-emitting surface.

In some selectable embodiments, the surface of the second part is exposed and patterned or roughened, and is formed to have a flatness within a range of 1 μm.

In some selectable embodiments, the first ohmic contact layer is InP, and a doping concentration of the first ohmic contact layer is greater than or equal to 4×10¹⁸/cm³.

In some selectable embodiments, a thickness of the first ohmic contact layer is 0.05 μm to 0.1 μm.

In some selectable embodiments, the semiconductor epitaxial lamination layer is bonded to the substrate via a bonding layer.

In some selectable embodiments, a reflective layer is disposed between the semiconductor epitaxial lamination layer and the substrate.

In some selectable embodiments, the infrared light-emitting diode radiates infrared light of 950 nm to 2000 nm.

The disclosure proposes an infrared light-emitting diode package. The infrared light-emitting diode package includes the aforementioned infrared light-emitting diode.

The disclosure proposes a red light-emitting device. The red light-emitting device includes the aforementioned infrared light-emitting diode.

The disclosure proposes an infrared light-emitting diode, which has at least the following advantageous effects.

The disclosure elevates the adhesion between the first electrode and the semiconductor epitaxial lamination layer by the configuration of the adhesion layer, enhances the bonding strength of the electrode, thereby improving the reliability of the infrared light-emitting diode.

Other features and advantages of the disclosure are elaborated in the following description, and become partially apparent from the description, or may be understood by implementing the disclosure. The objectives and other advantages of the disclosure may be realized and obtained by the structure specifically pointed out in the description, claims, and drawings.

Although the disclosure is described in conjunction with some exemplary embodiments and methods of use in the following, those skilled in the art should understand that it is not intended to limit the disclosure to these embodiments. On the contrary, it is intended to cover all alternatives, modifications, and equivalents that fall within the spirit and scope of the disclosure as defined by the appended claims.

### BRIEF DESCRIPTION OF THE DRAWINGS

In order to more clearly illustrate the technical solutions in the embodiments of the disclosure or in the related art, a brief introduction is given below to the drawings that need to be used in the description of the embodiments or the related art. Obviously, the drawings described below are some embodiments of the disclosure. For those skilled in the art, other drawings may be obtained based on these drawings without creative labor.

FIG. 1 is a side cross-sectional view of an infrared epitaxial structure according to Embodiment 1.

FIG. 2 is a side cross-sectional view of an infrared light-emitting diode according to Embodiment 1.

FIG. 3 to FIG. 4 are structural schematic diagrams during a preparation process of an infrared light-emitting diode according to Embodiment 2.

FIG. 5 is a structural schematic diagram of a light-emitting device according to Embodiment 3.

### DESCRIPTION OF THE EMBODIMENTS

To make the purpose, technical solutions, and advantages of the embodiments of the disclosure clearer, the technical solutions in the embodiments of the disclosure are described clearly and completely in conjunction with the drawings in the embodiments of the disclosure. Obviously, the described embodiments are part of the embodiments of the disclosure, not all of the embodiments. Based on the embodiments in the disclosure, all other embodiments obtained by those skilled in the art without creative labor fall within the scope of protection of the disclosure.

In the description of the disclosure, it needs to be explained that terms such as “center”, “longitudinal”, “transverse”, “upper”, “lower”, “front”, “rear”, “left”, “right”, “vertical”, “horizontal”, “top”, “bottom”, “inner”, “outer” indicating orientations or positional relationships are based on the orientations or positional relationships shown in the drawings, and are only for the convenience of describing the disclosure and simplifying the description, and do not indicate or imply that the referred device or element must have a specific orientation, be constructed and operated in a specific orientation, which therefore should not be understood as limitations on the disclosure.

Furthermore, terms such as “first”, “second”, and similar words do not indicate any order, number, or importance, but are only used to distinguish different components. Similar words such as “connect” or “connected” are not limited to physical or mechanical connections, but may include electrical connections, optical connections, etc., whether direct or indirect.

It should be understood that the terminology used in the disclosure is for the purpose of describing specific implementations only and is not intended to limit the disclosure. It is further understood that when being used in the disclosure, the terms “comprise” and “include” are used to indicate the presence of stated features, wholes, steps, elements, and/or components, but do not preclude the presence or addition of one or more other features, wholes, steps, elements, components, and/or combinations thereof.

Unless otherwise defined, all terms (including technical and scientific terms) used in the disclosure have the same meanings as commonly understood by those skilled in the field to which the disclosure belongs. It should be further understood that the terms used in the disclosure should be interpreted as having meanings consistent with their meanings in the context of this specification and the relevant field, and should not be understood in an idealized or overly formal sense unless explicitly defined as such in the disclosure.

### Embodiment 1

This embodiment proposes an infrared light-emitting diode, which may elevate adhesion between an electrode and a semiconductor epitaxial lamination layer, elevate the bonding strength of the electrode, and thereby elevate the reliability of the infrared light-emitting diode by inserting an adhesion layer between a first electrode and the semiconductor epitaxial lamination layer.

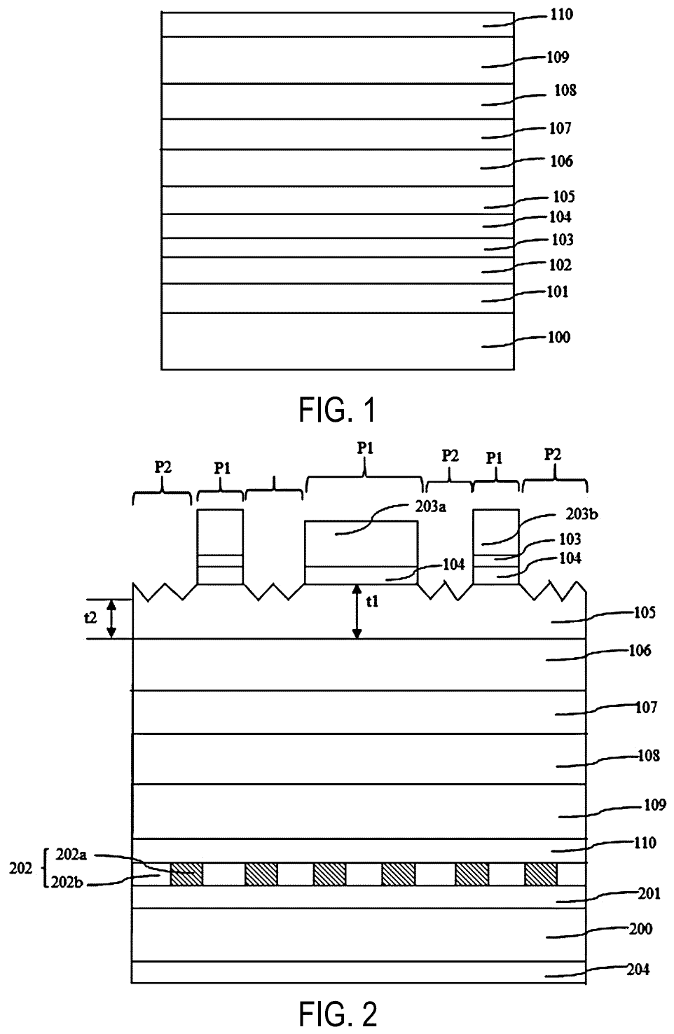

FIG. 1 is a schematic diagram of an LED epitaxial structure of a preferred embodiment. The LED epitaxial structure includes a growth substrate 100 and a semiconductor epitaxial lamination layer including a first window 105, a first cladding layer 106, an active layer 107, a second cladding layer 108, a second window layer 109, and a second ohmic contact layer 110 stacked in sequence on the growth substrate 100.

Specifically, with reference to FIG. 1, a material of the growth substrate 100 includes but is not limited to InP, and other materials may also be used, such as GaP and GaAs. In this embodiment, the growth substrate 100 including InP is taken as an example. Optionally, a buffer layer 101, an etch stop layer 102, and a first ohmic contact layer 103 are sequentially disposed between the growth substrate 100 and a first window layer 104. Since the lattice quality of the buffer layer 101 is better than that of the growth substrate 100, growing the buffer layer 101 on the growth substrate 100 is beneficial to eliminate the influence of lattice defects of the growth substrate 100 on the semiconductor epitaxial lamination layer. The etch stop layer 102 is an etch stop layer for subsequent chemical etching steps. In some optional embodiments, the etch stop layer 102 is an n-type etch stop layer 102, and the material is n-InGaAs. In order to facilitate the subsequent removal of the growth substrate 100, it is preferable to set a thinner etch stop layer 102 having a thickness less than 500 nm, or preferably less than 200 nm. In some optional embodiments, the first ohmic contact layer 103 is InP, with a thickness range of 10 nm to 100 nm, and an n-type doping concentration of 1×10¹⁸/cm³ to 1×10¹⁹/cm³, preferably above 4×10¹⁸/cm³, to achieve better ohmic contact.

The semiconductor epitaxial lamination layer may be formed on the growth substrate 100 by methods such as physical vapor deposition (PVD), chemical vapor deposition (CVD), epitaxy growth technology, and atomic layer deposition (ALD).

The semiconductor epitaxial lamination layer is a semiconductor material capable of providing conventional radiation such as ultraviolet, blue, green, yellow, red, and infrared light. Specifically, the semiconductor epitaxial lamination layer may be a material that provides radiation with a wavelength of 200 nm to 2000 nm, such as common nitrides, particularly a gallium nitride-based semiconductor epitaxial lamination layer. The Gallium nitride-based epitaxial lamination layer commonly have doped elements such as aluminum and indium, which mainly provide radiation in the 200 nm to 550 nm waveband. Alternatively, a common aluminum gallium indium phosphide-based or aluminum gallium arsenide-based semiconductor epitaxial lamination layers mainly provides radiation in the 550 nm to 2000 nm waveband. In this embodiment, the semiconductor epitaxial lamination layer is preferably an aluminum gallium arsenide-based semiconductor epitaxial lamination layer, mainly providing infrared radiation in the 950 nm to 2000 nm waveband, preferably infrared radiation in the 1450 nm waveband.

The semiconductor epitaxial lamination layer has a first surface and a second surface opposite to each other, and includes a first type semiconductor layer, an active layer, and a second type semiconductor layer stacked in sequence along a direction from the first surface towards the second surface. The first type semiconductor layer includes a first ohmic contact layer 103, a first window layer 105, and a first cladding layer 106 along the direction from the first surface towards the second surface. The second type semiconductor layer includes a second cladding layer 108, a second window layer 109, and a second ohmic contact layer 110.

The first window layer 105 serves the function of current spreading, and the spreading capability thereof is related to the thickness. Therefore, in this embodiment, the thickness may be selected according to the specific device dimensions. The preferred thickness is controlled to be larger than 2000 nm and less than 10000 nm. In this embodiment, the optimal thickness of the aforementioned first window layer 105 is 5000 nm to 9000 nm, which may ensure uniform current spreading. To enhance the luminous efficiency of the infrared light-emitting diode, this embodiment roughens the light-emitting surface of the infrared light-emitting diode. As AlₓGa₁₋ₓInAs material is suitable for wet etching, this embodiment preferentially selects AlₓGa₁₋ₓInAs as the material for the first window layer 105. By roughening a light-emitting surface of the first window layer 105, the luminous efficiency of the infrared light-emitting diode is improved. In this embodiment, the range of x is 0<x≤0.25. A doping concentration of the aforementioned first window layer 105 is 2×10¹⁷/cm3 to 4×10¹⁸/cm3.

Since a material of the first window layer 105 is AlₓGa₁₋ₓInAs, which is prone to oxidation in air, resulting in poor adhesion between the first window layer and the first electrode, and leading to issues such as electrode detachment and poor current spreading in the infrared light-emitting diode, which causes problems of electrode detachment and low brightness. In this embodiment, an adhesion layer 104 is inserted between the first ohmic contact layer 103 and the first window layer 105, enhancing the adhesion between the first electrode and the semiconductor epitaxial lamination layer, improving the bonding strength of the electrode, thereby elevating the reliability of the infrared light-emitting diode.

In this embodiment, a material of the adhesion layer 104 does not contain Al element, which has the stable chemical property, and is not prone to oxidation, enhancing the adhesion between the first electrode and the adhesion layer, thereby elevating the bonding strength of the infrared light-emitting diode. In this embodiment, the adhesion layer 104 may be InP, GaAs, InGaAs, or GaInP, preferably InP material. A thickness of the adhesion layer 104 may be 300 nm to 800 nm, preferably 500 nm. A doping concentration of the adhesion layer 104 may be 1×10¹⁷/cm³ to 9×10¹⁷/cm³, preferably 7×10¹⁷ to 8×10¹⁷/cm³. By limiting the doping concentrations of the first ohmic contact layer 103 and the adhesion layer 104, the current spreading capability of the infrared light-emitting diode may be enhanced, and the light emission efficiency of the infrared light-emitting diode is elevated.

The first cover layer 106 and the second cover layer 108 in the semiconductor epitaxial lamination layer have different doping types respectively. In this embodiment, the first cover layer 106 provides n-type electrons, and the second cover layer 108 provides p-type holes. By doping elements, the first cover layer 106 or the second cover layer 108 with n-type or p-type doping may be implemented. A bandgap of the first cover layer 106 and a bandgap of the second cover layer 108 are both greater than a bandgap of the active layer 107. The first cover layer 106 may implement n-type doping by doping Si or Te. The second cover layer 108 may implement p-type doping by doping C, Zn or Mg. In this embodiment, a material of the first cover layer 106 is AlₐIn₁₋ₐAs, where a range of “a” is 0.3 to 0.55. A thickness of the first cover layer 106 may be 0.3 to 1 μm, and the doping concentration may be 1×10¹⁷ to 5×10¹⁷/cm³, to provide sufficient electrons.

The active layer 107 is a region providing light radiation for a recombination of electrons and holes. Different materials may be selected according to different emission wavelengths. The active layer 107 may be a periodic structure of single quantum well or multiple quantum wells. The active layer 107 includes a quantum well layer and a quantum barrier layer, where the quantum barrier layer possess larger bandgaps than the quantum well layer. By adjusting the composition ratio of semiconductor materials in the active layer 107, light with different wavelengths may be expected to radiate. The active layer 107 is a material layer providing electroluminescence radiation, such as aluminum gallium indium phosphide or indium gallium arsenide, more preferably indium gallium arsenide, which may be a single quantum well or multiple quantum wells. In this embodiment, the active layer 107 is a multiple quantum well structure, and the number of periods of the active layer 107 may be 3 to 15, and preferably 5 to 15 periods. Preferably, a material of the quantum well layer may be Alₓ₁Ga_{y1}In_{1-x1-y1}As, where 0≤x1≤0.5, 0≤y1≤0.5; the material of the quantum well layer or the quantum barrier layer may be Alₓ₂Ga_{y2}In_{1-x2-y2}As, where 0≤x2≤0.5, 0≤y2≤0.5, or Inₓ₃Ga₁₋ₓ₃As_{y3}P_{1-y3}, where 0.4≤x3≤0.7, 0≤y3≤1. A thickness of the quantum well layer may be 80 Å to 130 Å, and the thickness of the quantum barrier layer may be 90 Å to 140 Å.

In this embodiment, a material of the second cover layer 108 may be Al_{b}In_{1-b}As, where the range of b may be 0.3 to 0.55. A thickness of the second cover layer 108 may be 0.3 μm to 1 μm, and a doping concentration may be 1×10¹⁷/cm³ to 5×10¹⁷/cm³, to provide sufficient holes.

The second window layer 109 serves the function of current spreading, and the spreading capability thereof is related to the thickness. Therefore, in this embodiment, the thickness may be selected according to the specific device dimensions. Preferably, the thickness of the second window layer 109 may be 800 nm to 3000 nm, which may ensure uniform current spreading. A material of the second window layer 109 may be InP. The second window layer 109 may be p-type doped, with a doping concentration of 2×10¹⁷/cm³ to 4×10¹⁸/cm³.

The second ohmic contact layer 110 may form an ohmic contact with the second electrode 204. A material may be InP, InGaAs or InGaAsP, with a doping concentration of 5×10¹⁸/cm³, more preferably 1×10¹⁹/cm³ or above, to achieve better ohmic contact. A thickness of the second ohmic contact layer 110 shown may preferably be larger than 30 nm and less than 100 nm. In this implementation, a thickness of the second ohmic contact layer 109 may preferably be 50 nm.

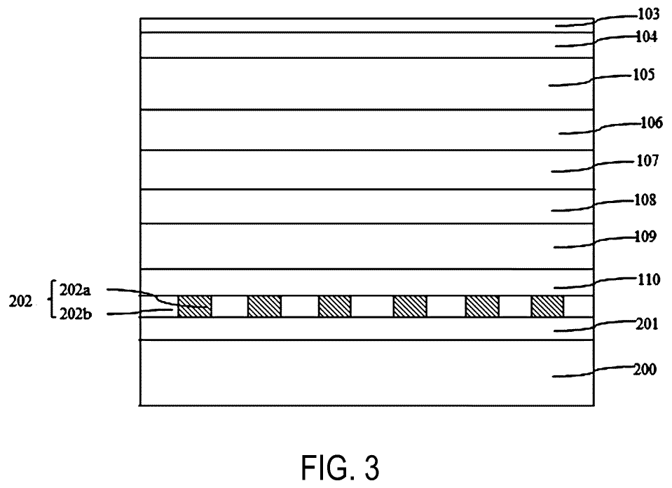

FIG. 2 shows a schematic diagram of an infrared light-emitting diode, which adopts the epitaxial structure shown in FIG. 1. The infrared light-emitting diode may include a substrate 200, and the semiconductor epitaxial lamination layer may be bonded to the substrate 200 by a bonding layer 201. The semiconductor epitaxial lamination layer may include a second ohmic contact layer 110, a second window layer 109, a second cladding layer 108, an active layer 107, a first cladding layer 106, a first window layer 105, an adhesion layer 104, and a first ohmic contact layer 103 stacked in sequence on the substrate 200.

The substrate 200 may be a conductive substrate, which may be silicon, silicon carbide, or a metal substrate. The metal substrate may preferably be copper, tungsten, or molybdenum substrate. To support the semiconductor epitaxial lamination layer with sufficient mechanical strength, a thickness of the substrate 200 may preferably be 50 μm or above. Additionally, to facilitate mechanical processing of the substrate 200 after bonding to the semiconductor epitaxial lamination layer, the thickness of the substrate 200 may preferably not exceed 300 μm. In this embodiment, the substrate 200 may preferably be a silicon substrate.

The first electrode 203 may comprise a main electrode 203a and multiple extending electrodes 203b, with the extending electrodes 203b extending outward from the main electrode 203a. The extending electrodes 203b of the first electrode 203 may be set on the first ohmic contact layer 103, forming an ohmic contact between the extending electrodes 203b in the first electrode 203 and the first ohmic contact layer 103 to achieve current flow. The first ohmic contact layer 103 may only retain the part located vertically below the extending electrodes 203b. The adhesion layer 104 may be included between the main electrode 203a of the first electrode 203 and the first window layer 105. The adhesion layer 104 may elevate the adhesion between the main electrode of the first electrode and the semiconductor epitaxial lamination layer, elevating the bonding strength of the first electrode, thereby elevating the reliability of the infrared light-emitting diode. The doping concentration of the adhesion layer 104 may be lower than that of the first ohmic contact layer 103 and the first window layer 105, which may elevate the current spreading capability and elevate the light-emitting efficiency of the infrared light-emitting diode.

The first window layer 105 may include two parts in the horizontal direction, namely, a part P1 located under the first electrode 203, and a part P2 not located under the first electrode 203, which may be exposed and defined as a light-emitting surface. The light-emitting surface of the first window layer 105 may be formed surrounding the first electrode 203. The light-emitting surface may be further formed into a patterned surface or a roughened surface through an etching process, where the patterned surface may be obtained through etching. The roughened surface may have a regular surface structure or any arbitrary irregular surface micro-nano structure. The roughened surface or the patterned surface may allow the light from the light-emitting layer to escape more easily, elevating the light extraction efficiency. Preferably, the light-emitting surface may be a roughened surface, with the height difference (or high-low difference) of the surface structure formed by roughening being less than 1 micron, preferably 10 to 30 nm.

The first window layer 105 may include a second surface of the part P1 located only under the first electrode 203, which may not be roughened as the second surface may be protected by the first electrode 203. The horizontal height of the roughened surface of the first window layer 105 may be substantially lower than the horizontal height of the second surface (interface) located under the first electrode 203 due to the roughening process.

Specifically, in this embodiment, as shown in FIG. 2, the first window layer 105 may include a part P1 located under the first electrode 203 and a part P2 not located under the first electrode 203. The first window layer 105 may have a first thickness t1 in the part P1 covered by the electrode, and the first window layer 105 not covered by the first electrode may have a second thickness t2. Preferably, the first thickness t1 may be 1.5 to 2.5 microns, and the second thickness t2 may be 0.5 μm to 1.5 μm. The thickness t1 of part P1 may be greater than the thickness t2 of part P2. More preferably, the first thickness t1 may be at least 0.3 μm greater than the second thickness t2.

A mirror layer 202 may be set between the semiconductor epitaxial lamination layer and the substrate 200. The mirror layer 202 may include a P-type ohmic contact metal layer 201a and a dielectric material layer 201b, thereby forming an ohmic contact with the second ohmic contact layer 110, and reflecting the light beam emitted from the active layer 107 to the light-emitting surface of the first window layer 104 or the sidewall of the semiconductor epitaxial lamination layer for light emission.

The infrared light-emitting diode may also include a second electrode 204. In some embodiment, the second electrode 204 may be located on the back side of the substrate 200. Alternatively, the second electrode 204 may be located on the substrate 200, on the same side as the semiconductor epitaxial lamination layer.

The first electrode 203 and the second electrode 204 may include a transparent conductive material and/or a metal material. The transparent conductive material may include a transparent conductive layer, such as ITO or IZO. The metal material may include at least one of GeAuNi, AuGe, AuZn, Au, Al, Pt, and Ti.

The disclosure may elevate the adhesion between the electrode and the semiconductor epitaxial lamination layer, enhance the bonding strength of the electrode, and thereby elevate the reliability of the infrared light-emitting diode by inserting an adhesion layer between the first electrode and the semiconductor epitaxial lamination layer.

### Embodiment 2

The high-brightness infrared light-emitting diode of the disclosure is explained in detail below in combination with the manufacturing method.

First, an epitaxial structure is provided, as shown in FIG. 1, which specifically includes: providing a growth substrate 100, preferably InP, on which a semiconductor epitaxial lamination layer is epitaxially grown through an epitaxial process such as MOCVD. The semiconductor epitaxial lamination layer includes a buffer layer 101 and an etch stop layer 102 stacked in sequence on the surface of the growth substrate 100. The buffer layer 101 and the etch stop layer 102 are configured to remove the epitaxial growth substrate 100. Then, the first ohmic contact layer 103, the adhesion layer 104, the first window layer 105, the first cover layer 106, the active layer 107, the second cover layer 108, the second window layer 109, and the second ohmic contact layer 110 are grown.

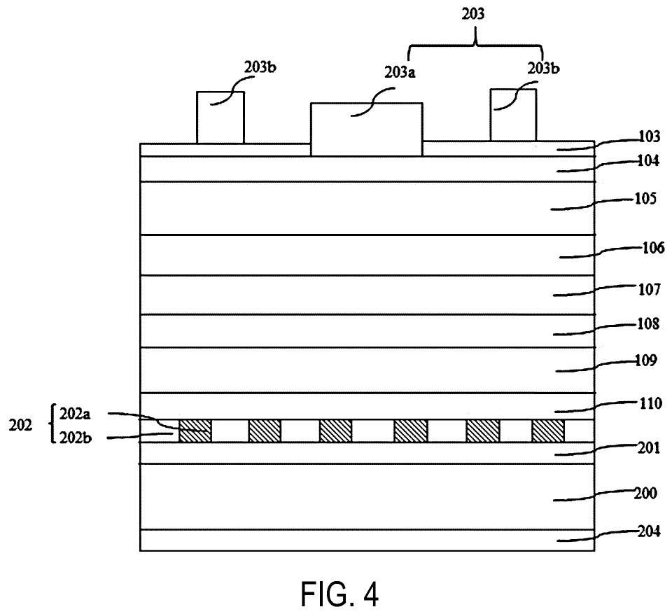

Next, the semiconductor epitaxial lamination layer is transferred to the substrate 200, and the growth substrate 100 is removed to obtain the structure shown in FIG. 3, which specifically includes the following steps. The mirror layer 202 is manufactured on the second ohmic contact layer 110, which includes a P-type ohmic contact metal layer 202a and a dielectric material layer 202b, thereby forming an ohmic contact with the second ohmic contact layer 110 and reflecting light directed downward from the active layer. The substrate 200 is provided. The metal bonding layer 201 is disposed on the substrate 200. The substrate 201 is bonded with the mirror layer 202. The growth substrate 100 is removed. In the case where the growth substrate 100 is InP, a wet etching process may be adopted for removal until the first ohmic contact layer 103 is exposed.

Next, the first ohmic contact layer 103 at a position of a main electrode is removed by masking. The main electrode 203a of the first electrode 203 is formed on the adhesion layer 104. The extending electrode 203b of the first electrode 203 is formed on the first ohmic contact layer 103. The extending electrode 203a of the first electrode 203 forms a good ohmic contact with the first ohmic contact layer 103. The second electrode 204 is formed on the back side of the substrate 200. Thereby, a current is conducted between the first electrode 203 and the second electrode 204 by the semiconductor epitaxial lamination layer. The substrate 200 has a certain thickness to support all layers above the substrate 200.

Then, a mask is formed to cover the first electrode 203, with the first ohmic contact layer 103 around the first electrode 203 being exposed. An etching process is conducted to remove the first ohmic contact layer 103 and the adhesion layer 104 around the first electrode 203, so that the ohmic contact layer 103 and the adhesion layer 104 not located under the first electrode 109 are completely removed, while the first window layer 105 is exposed. Subsequently, the first window layer 105 is etched to form a patterned or roughened surface, forming the structure as shown in FIG. 2. The removal process of the first ohmic contact layer 103 and the adhesion layer 104, as well as the roughening treatment of the first window layer 105, may be a single step or multiple steps of wet etching process. The solution for wet etching may be an acidic solution, such as hydrochloric acid, sulfuric acid, hydrofluoric acid, citric acid, or any other preferable chemical reagent.

Finally, according to size requirements, a unit infrared light-emitting diode may be obtained by processes such as etching and cleaving.

### Embodiment 3

The embodiment of the disclosure provides a package of an infrared light-emitting diode. The package of the infrared light-emitting diode includes multiple light-emitting diodes arranged in an array as described in any of the aforementioned embodiments.

In this embodiment, the package of the infrared light-emitting diode may be used as a light source for sensors, which is widely selected in fields such as wireless earphones and smart wearable devices.

Due to having the light-emitting diodes of the aforementioned embodiments, the package of the infrared light-emitting diode has the advantages brought by the light-emitting diodes of the aforementioned embodiments.

### Embodiment 4

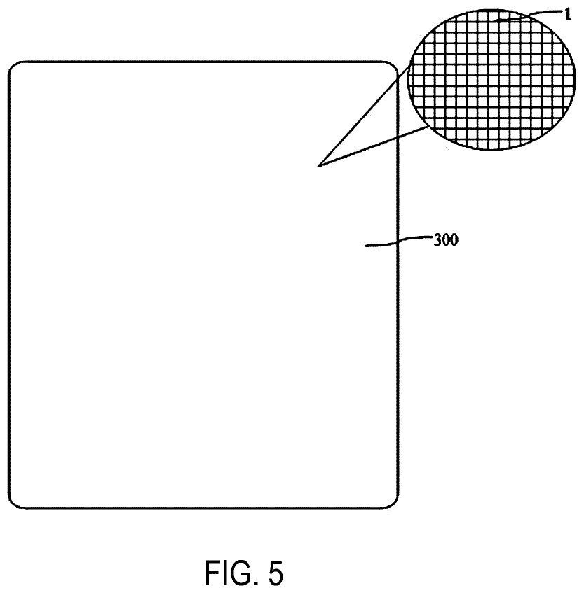

The embodiment of the disclosure provides a light-emitting device 300. With reference to FIG. 5, the light-emitting device 300 includes the light-emitting diodes arranged in an array as described in any of the aforementioned embodiments. In FIG. 5, a part of the light-emitting diodes 1 is shown in an enlarged schematic manner.

In this embodiment, the light-emitting device 300 may be used as a light source for sensors, which is widely selected in fields such as wireless earphones and smart wearable devices.

Due to having the light-emitting diodes of the aforementioned embodiments, the light-emitting device 300 has the advantages brought by the light-emitting diodes of the aforementioned embodiments.

It should be noted that the above embodiments are only used to illustrate the disclosure, and are not intended to limit the disclosure. The technicians in this field may make various modifications and variations to the disclosure without departing from the spirit and scope of the disclosure. Therefore, all equivalent technical solutions also fall within the scope of the disclosure. The patent protection scope of the disclosure should be limited by the scope of the claims.

What is claimed is:

1. An infrared light-emitting diode, comprising:
a semiconductor epitaxial lamination layer, having a first surface and a second surface opposite to each other, the semiconductor epitaxial lamination layer comprising a first type semiconductor layer, an active layer, and a second type semiconductor layer stacked in sequence along a direction from the first surface towards the second surface, wherein the first type semiconductor layer comprises a first ohmic contact layer, a first window layer, and a first cladding layer along the direction;
a first electrode, located on the first type semiconductor layer, and comprising a main electrode and a plurality of extending electrodes, the plurality of extending electrodes extending outward from the main electrode; and
an adhesion layer, located between the first window layer and the main electrode of the first electrode.

2. The infrared light-emitting diode according to claim 1, wherein the adhesion layer does not comprise Al element.

3. The infrared light-emitting diode according to claim 1, wherein a material of the adhesion layer comprises at least one of InGaAs, GaAs, InP, and GaInP.

4. The infrared light-emitting diode according to claim 1, wherein a thickness of the adhesion layer is 0.3 μm to 0.7 μm.

5. The infrared light-emitting diode according to claim 1, wherein a doping concentration of the adhesion layer is 1×10¹⁷/cm³ to 9×10¹⁷/cm³.

6. The infrared light-emitting diode according to claim 1, wherein the adhesion layer is located between the first ohmic contact layer and the first window layer.

7. The infrared light-emitting diode according to claim 1, wherein a material of the first window layer is AlₓGa₁₋ₓInAs, and 0<x≤0.25.

8. The infrared light-emitting diode according to claim 1, wherein the first window layer comprises a first part covered by the first electrode, and a thickness of the first part is 6 μm to 8 μm.

9. The infrared light-emitting diode according to claim 8, wherein the first window layer comprises a second part not covered by the first electrode, and a thickness of the second part is 0.5 μm to 1.5 μm.

10. The infrared light-emitting diode according to claim 9, wherein a surface of the second part is exposed and patterned or roughened, so as to provide a light-emitting surface of the infrared light-emitting diode.

11. The infrared light-emitting diode according to claim 10, wherein the surface of the second part is exposed and patterned or roughened, and is formed to have a flatness within a range of 1 μm.

12. The infrared light-emitting diode according to claim 1, wherein the first ohmic contact layer is InP, a doping concentration of the first ohmic contact layer is greater than or equal to 4×10¹⁸/cm³.

13. The infrared light-emitting diode according to claim 12, wherein a thickness of the first ohmic contact layer is 0.05 μm to 0.1 μm.

14. The infrared light-emitting diode according to claim 1, wherein the semiconductor epitaxial lamination layer is bonded to the substrate via a bonding layer.

15. The infrared light-emitting diode according to claim 1, wherein a reflective layer is disposed between the semiconductor epitaxial lamination layer and the substrate.

16. The infrared light-emitting diode according to claim 1, wherein the infrared light-emitting diode radiates infrared light of 950 nm to 2000 nm.

17. An infrared light-emitting diode package, comprising the infrared light-emitting diode according to claim 1.

18. An infrared light-emitting device, comprising the infrared light-emitting diode according to claim 1.
